(19) United States
(12) Patent Application Publication
(10) Pub. No.: US 2025/0209587 A1
(43) Pub. Date: Jun. 26, 2025

(54) APPARATUS AND METHOD FOR DIAGNOSING BATTERY, AND COMPUTER PROGRAM

(71) Applicants: SAMSUNG SDI CO., LTD., Yongin-si (KR); ULSAN NATIONAL INSTITUTE OF SCIENCE AND TECHNOLOGY, Ulsan (KR)

(72) Inventors: Seong Ho WOO, Suwon-si (KR); Hyun Wook LEE, Ulsan (KR); Dae Sik KIM, Suwon-si (KR); Sung Kook LEE, Suwon-si (KR); Ji Young KIM, Suwon-si (KR); Bo Ram LEE, Suwon-si (KR); Chang Hyun PARK, Ulsan (KR); Uk Hyun JUNG, Ulsan (KR)

(21) Appl. No.: 18/651,429

(22) Filed: Apr. 30, 2024

(30) Foreign Application Priority Data
Dec. 21, 2023 (KR) 10-2023-0188680

(51) Int. Cl. G06T 7/00; G01N 23/046; G06T 3/067

(52) U.S. Cl. CPC G06T 7/0002; G01N 23/046; G06T 3/067; G01N 2223/401; G01N 2223/611; G06T 2207/10081

(57) ABSTRACT

An apparatus for diagnosing a battery, the apparatus including a processor; and a memory storing instructions that, when executed on the processor, cause the processor to perform: generating a plurality of cross-sectional images of the battery from a three-dimensional (3D) image of the battery; plotting a plurality of points according to pixel values of a cross-sectional image of the plurality of cross-sectional images on the cross-sectional image to generate plot data in which at least some of the points are rounded; generating a two-dimensional (2D) flat image, in which the 3D image of the battery is spread out, by linearizing the generated plot data; and diagnosing the battery based on the generated 2D flat image.

### CROSS-REFERENCE TO RELATED APPLICATION

The present application claims priority to and the benefit of Korean Patent Application No. 10-2023-0188680, filed on Dec. 21, 2023, in the Korean Intellectual Property Office, the entire disclosure of which is incorporated herein by reference.

### BACKGROUND

### 1. Field

Aspects of embodiments of the present disclosure relate to a technique for diagnosing battery cells.

### 2. Description of the Related Art

Secondary batteries are batteries that can be charged or discharged, unlike primary batteries that cannot be recharged. Low-capacity secondary batteries are used in small portable electronic devices such as smartphones, feature phones, laptop computers, digital cameras, and camcorders, and high-capacity secondary batteries are widely used as power sources for driving motors of hybrid vehicles, electric vehicles, etc., as batteries for power storage, etc. Such a secondary battery includes an electrode assembly consisting of a positive electrode and a negative electrode, a case accommodating the electrode assembly, an electrode terminal connected to the electrode assembly, and the like.

Battery cells, such as lithium-ion cells applied to secondary batteries, undergo chemical reactions within the battery cells due to continuous charging or discharging, resulting in cell deterioration and performance degradation. In particular, internal deformation of battery cells that occurs during charging or discharging is a major factor affecting deterioration and performance degradation. In order to analyze the deterioration phenomenon, destructive analysis, which generally involves disassembling battery cells and conducting analysis, was mainly used. However, such destructive analysis inevitably causes internal damage during the disassembly process of the battery cells, makes it difficult to determine an actual cause of performance deterioration, and is limited in confirming the deterioration tendency as charging and discharging progresses.

The above information disclosed in this Background section is for enhancement of understanding of the background of the present disclosure, and therefore, it may contain information that does not constitute related (or prior) art.

### SUMMARY

Aspects of some embodiments of the present disclosure are directed to an apparatus and method for diagnosing a battery, in which an abnormality such as deformation of battery cells is diagnosed, and a computer program for executing the same. In some embodiment, the diagnosis may be performed by computed tomography (CT) that is a non-destructive analysis method beyond the limitations of battery cell diagnosis according to the destructive analysis methods of the related art.

However, objects that the present invention intends to achieve are not limited to the above-described objects, and other objects that are not described may be clearly understood by those skilled in the art from the following description.

According to some embodiments of the present invention, there is provided a battery diagnosis apparatus in which a two-dimensional (2D) flat image, in which a three-dimensional (3D) image of a battery cell is spread out, is generated and deformation of an internal structure of the battery cell is diagnosed by analyzing greyscale intensity using pixel values of the 2D flat image.

According to some embodiments of the present disclosure, there is provided an apparatus for diagnosing a battery, the apparatus including: a processor; and a memory storing instructions that, when executed on the processor, cause the processor to perform: generating a plurality of cross-sectional images of the battery from a three-dimensional (3D) image of the battery; plotting a plurality of points according to pixel values of a cross-sectional image of the plurality of cross-sectional images on the cross-sectional image to generate plot data in which at least some of the points are rounded; generating a two-dimensional (2D) flat image, in which the 3D image of the battery is spread out, by linearizing the generated plot data; and diagnosing the battery based on the generated 2D flat image.

In some embodiments, the processor is configured to generate the plurality of cross-sectional images by slicing the 3D image at preset intervals relative to a first axis direction with respect to the battery.

In some embodiments, the processor is configured to generate the plot data for each one of the plurality of cross-sectional images, and to generate the 2D flat image by linearizing the plot data generated for each one of the plurality of cross-sectional images.

In some embodiments, the processor is configured to generate the 2D flat image by aligning the plot data relative to the first axis direction.

In some embodiments, as a process for generating the plot data, the processor is configured to plot a center point on a center of the cross-sectional image, and to plot a plurality of reference points on a plurality of positions where peaks of the pixel values of the cross-sectional image appear on an imaginary line extending from the center point to an outside of the cross-sectional image.

In some embodiments, the processor is configured to generate the plot data by plotting points while tracking positions having same pixel values as the plurality of reference points.

In some embodiments, the 3D image and the cross-sectional images of the battery are implemented as computed tomography (CT) images, and a pixel value of the cross-sectional image is a greyscale intensity of the CT image.

In some embodiments, the processor is configured to diagnose deformation of an internal structure of the battery based on the 2D flat image.

According to some embodiments of the present disclosure, there is provided a method of diagnosing a battery, the method including: generating, by a processor, a plurality of cross-sectional images of the battery from a three-dimensional (3D) image of the battery; plotting, by the processor, a plurality of points according to pixel values of a cross-sectional image of the plurality of cross-sectional images on the cross-sectional image and generating plot data in which at least some of the points are rounded; generating, by the processor, a two-dimensional (2D) flat image, in which the 3D image of the battery is spread out, by linearizing the generated plot data; and diagnosing, by the processor, the battery based on the generated 2D flat image.

In some embodiments, in the generating of the cross-sectional images, the processor is configured to generate the plurality of cross-sectional images by slicing the 3D image at preset intervals relative to a first axis direction with respect to the battery.

In some embodiments, the plot data are generated for each one of the plurality of cross-sectional images, and wherein, in the generating of the 2D flat image, the processor is configured to generate the 2D flat image by linearizing the plot data generated for each one of the plurality of cross-sectional images.

In some embodiments, in the generating of the 2D flat image, the processor is configured to generate the 2D flat image by aligning the plot data relative to the first axis direction.

In some embodiments, in the generating of the plot data, the processor is configured to plot a center point on a center of the cross-sectional image, and to plot a plurality of reference points on a plurality of positions where peaks of the pixel values of the cross-sectional image appear on an imaginary line extending from the center point to an outside of the cross-sectional image.

In some embodiments, in the generating of the plot data, the processor is configured to generate the plot data by plotting points while tracking positions having same pixel values as the plurality of reference points.

In some embodiments, in the diagnosing of the battery, the processor is configured to diagnose deformation of an internal structure of the battery based on the 2D flat image.

According to some embodiments of the present disclosure, there is provided a computer program, which is coupled to hardware and stored in a computer-readable storage medium, for performing operations of: generating a cross-sectional image of a battery from a three-dimensional (3D) image of the battery; plotting a plurality of points according to pixel values of the generated cross-sectional image on the cross-sectional image and generating plot data in which at least some of the points are rounded; generating a two-dimensional (2D) flat image, in which the 3D image of the battery is spread out, by linearizing the generated plot data; and diagnosing the battery based on the generated 2D flat image.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 illustrates a cylindrical battery according to some embodiments of the present invention;

FIG. 2 is a cross-sectional view of a cylindrical battery according to some embodiments of the present invention;

FIG. 3 is a block diagram of a battery diagnosis apparatus according to some embodiments of the present invention;

FIGS. 4A-4G illustrate a set of diagrams of a process for generating a two-dimensional (2D) flat image from a three-dimensional (3D) computed tomography (CT) image in a battery diagnosis apparatus according to some embodiments of the present invention;

FIG. 5 shows an example of a 2D flat image finally generated in a battery diagnosis apparatus according to some embodiments of the present invention;

FIG. 6 shows an example of internal deformation of a battery to be diagnosed in a battery diagnosis apparatus according to some embodiments of the present invention;

FIG. 7 shows an example of first to N^{th} zones of a 2D flat image in a battery diagnosis apparatus according to some embodiments of the present invention;

FIGS. 8 and 9 show examples of a process for diagnosing internal deformation of a battery in a battery diagnosis apparatus according to some embodiments of the present invention;

FIG. 10 shows an example of an intrinsic noise area reflected in a 2D flat image and an internal deformation area of a battery in a battery diagnosis apparatus according to some embodiments of the present invention;

FIGS. 11A-11B and 12 show examples of a process for distinguishing between an intrinsic noise area reflected in a 2D flat image and an internal deformation area of a battery in a battery diagnosis apparatus according to some embodiments of the present invention; and

FIG. 13 is a flowchart of a battery diagnosis method according to some embodiments of the present invention.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same”. The phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or provided in plural form.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

### 1. Diagnosis Target Battery

According to some embodiments, a diagnosis target may correspond to a battery to which a winding process such as a jelly roll is applied, and correspond to, for example, a cylindrical lithium-ion secondary battery or a prismatic lithium-ion secondary battery. Hereinafter, in order to help with understanding of embodiments, a battery to be diagnosed is described as being a cylindrical lithium-ion secondary battery (hereinafter, referred to as a “battery cell”); however, embodiments of the present disclosure are not limited thereto, and may be applied to various suitable structures and forms of batteries within a range manufactured according to a winding process of an electrode assembly (defined as a configuration including a positive electrode plate, a separator, and a negative electrode plate).

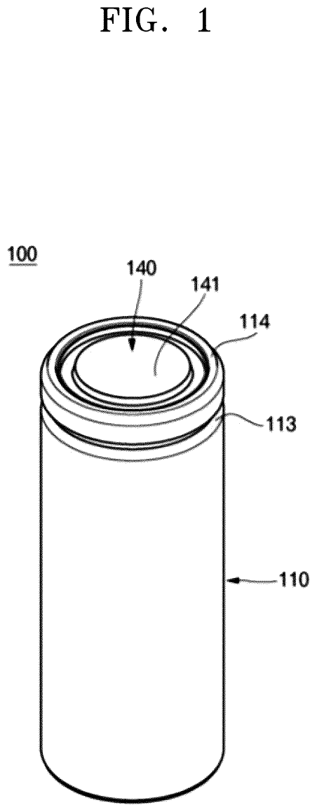

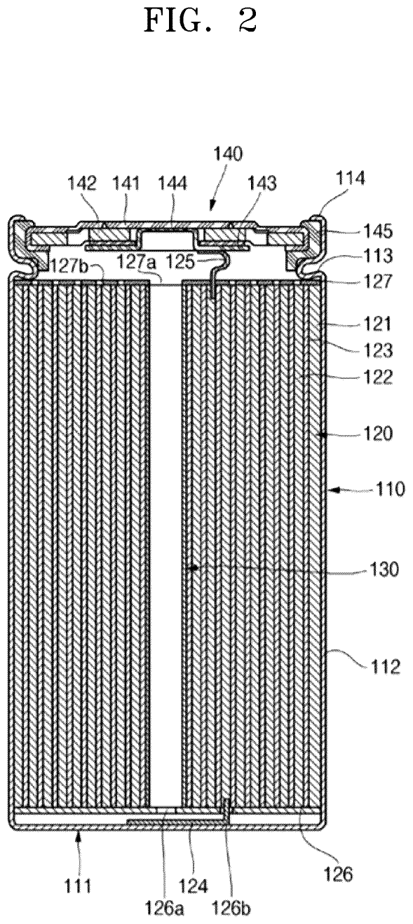

Prior to description of a battery diagnosis process according to some embodiments, a structure of a cylindrical battery cell illustrated in FIGS. 1 and 2, which is a battery cell that can be a diagnosis target, will first be briefly described.

As illustrated in FIGS. 1 and 2, a cylindrical battery cell 100 according to some embodiments may include a cylindrical can 110, an electrode assembly 120, and a cap assembly 140. Further, in some examples, the cylindrical battery cell 100 may further include a center pin 130. Further, in the battery cell 100 according to some embodiments of the present invention, the cap assembly 140 also performs a current interrupt operation, and thus, in some examples, the cap assembly 140 is referred to as a current interrupt device.

The cylindrical can 110 may include a substantially circular bottom part 111 and a cylindrical sidewall 112 extending a set or predetermined length from a periphery of the bottom part 111 upward. During part of the manufacturing process of the secondary battery, an upper part of the cylindrical can 110 may be open. Therefore, during the assembly process of the secondary battery, the electrode assembly 120 and the center pin 130 may be inserted into the cylindrical can 110 together with an electrolyte solution. The cylindrical can 110 may be made of, for example, but is not limited to, steel, stainless steel, aluminum, aluminum alloy, or equivalents thereof.

Further, the cylindrical can 110 may include a beading part 113 recessed inward at a lower part of the cap assembly 140 to prevent the cap assembly 140 from being separated to (e.g., exposed to) the outside or substantially reduce likelihood thereof, and a crimping part 114 bent inward on an upper part of the cap assembly 140.

The electrode assembly 120 may be accommodated inside the cylindrical can 110. The electrode assembly 120 may include a negative electrode plate 121 which is formed by coating a negative electrode active material (e.g., graphite, carbon, etc.) on a negative electrode current collector plate, a positive electrode plate 122 that is formed by coating a positive electrode active material (e.g., transition metal oxide (LiCoO₂, LiNiO₂, LiMn₂O₄, etc.) on a positive electrode current collector plate, and a separator 123 that is disposed between the negative electrode plate 121 and the positive electrode plate 122 to prevent a short circuit or substantially reduce likelihood thereof, and only allow movement of lithium ions. Further, the negative electrode plate 121, the positive electrode plate 122, and the separator 123 may be wound in a substantially cylindrical shape. Here, the negative electrode current collector plate may be made of, for example, but is not limited to, copper (Cu) foil, the positive electrode current collector plate may be made of aluminum (Al) foil, and the separator may be made of polyethylene (PE) or polypropylene (PP).

Further, a negative electrode tab 124 that protrudes and extends a set or predetermined length downward may be welded to the negative electrode plate 121, and a positive electrode tab 125 that protrudes and extends a set or predetermined length upward may be welded to the positive electrode plate 122, and vice versa. In addition, the negative electrode tab 124 may be formed of, for example, but is not limited to, copper (Cu) or nickel (Ni), and the positive electrode tab 125 may be formed of aluminum (Al).

Further, the negative electrode tab 124 of the electrode assembly 120 may be welded to the bottom part 111 of the cylindrical can 110. Therefore, the cylindrical can 110 may operate as a negative electrode. In some examples, the positive electrode tab 125 may be welded to the bottom part 111 of the cylindrical can 110, and in such examples, the cylindrical can 110 may operate as a positive electrode.

In addition, a first insulating plate 126, which is coupled to the cylindrical can 110 and has a first hole 126a formed in a center thereof and a second hole 126b formed in an outer side thereof, may be interposed between the electrode assembly 120 and the bottom part 111. The first insulating plate 126 serves to prevent the electrode assembly 120 from being electrically brought into contact with the bottom part 111 of the cylindrical can 110 or substantially reduces the likelihood thereof. In particular, the first insulating plate 126 serves to prevent the positive electrode plate 122 of the electrode assembly 120 from being electrically brought into contact with the bottom part 111 or substantially reduces the likelihood thereof. Here, when a large amount of gas is generated due to an abnormality in the secondary battery, the first hole 126a serves to rapidly move the gas upward through the center pin 130, and the second hole 126b serves to allow the negative electrode tab 124 to pass therethrough and be welded to the bottom part 111.

Further, a second insulating plate 127, which is coupled to the cylindrical can 110 and has a first hole 127a formed in a center thereof and a plurality of second holes 127b formed in an outer side thereof, may be interposed between the electrode assembly 120 and the cap assembly 140. The second insulating plate 127 serves to prevent the electrode assembly 120 from being electrically brought into contact with the cap assembly 140 or substantially reduces the likelihood thereof. In particular, the second insulating plate 127 serves to prevent the negative electrode plate 121 of the electrode assembly 120 from being electrically brought into contact with the cap assembly 140 or substantially reduces the likelihood thereof. Here, when a large amount of gas is generated due to an abnormality in the secondary battery, the first hole 127a serves to move the gas rapidly, and the second hole 127b serves to allow the positive electrode tab 125 to pass therethrough and be welded to the cap assembly 140. Further the remaining second holes 127b serve to allow an electrolyte solution to rapidly flow into the electrode assembly 120 during the electrolyte solution injection process.

In addition, diameters of the first holes 126a and 127a of the first and second insulating plates 126 and 127 are smaller than a diameter of the center pin 130, and thus the first holes 126a and 127a prevent the center pin 130 from being electrically brought into contact with the bottom part 111 of the cylindrical can 110 or the cap assembly 140 due to external shock or substantially reduce the likelihood thereof.

The center pin 130 has a shape of a hollow circular pipe or tube and may be coupled to approximately a center of the electrode assembly 120. The center pin 130 may be made of, for example, but is not limited to, steel, stainless steel, aluminum, aluminum alloy, or polybutylene terephthalate. The center pin 130 serves to suppress deformation of the electrode assembly 120 during charging or discharging of the battery, and serves as a path through which the gas generated inside the secondary battery moves. However, in some examples, the center pin 130 may be omitted.

The cap assembly 140 may include a top plate 141, a middle plate 142, an insulating plate 143, and a bottom plate 144.

The middle plate 142 may be located below the top plate 141 and may have a substantially flat shape.

The insulating plate 143 may be formed in a circular ring shape with a set or predetermined width when viewed from the bottom. Further, the insulating plate 143 serves to insulate the middle plate 142 and the bottom plate 144 from each other. The insulating plate 143 may be, for example, but is not limited to being, interposed between the middle plate 142 and the bottom plate 144 and welded using ultrasonic waves and/or the like.

The cylindrical battery cell 100 having the above-described structure may undergo deformation in an internal structure (e.g., electrode assembly) thereof as its lifetime progresses. When the deformation of the internal structure of the battery cell 100 has progressed significantly, the deformation of the internal structure of the battery cell 100 may be identified with the naked eye through a three-dimensional (3D) computed tomography (CT) image. However, there are limitations in that it is difficult to intuitively identify the deformation of the internal structure of the cylindrical battery cell 100, to which a winding process such as a jelly roll is applied, and it is difficult to identify minute deformations that occur in an early stage, in which the internal structure is deformed, with only the 3D CT image.

Accordingly, in some embodiments, a configuration is adopted in which a two-dimensional (2D) flat image in which the 3D CT image is spread out is generated by plotting the contrast of the electrode assembly 120 appearing in the 3D CT image of the battery cell 100 on the basis of grayscale intensity, and deformation of the internal structure of the battery cell 100 is diagnosed using the 2D flat image generated in this way. Hereinafter, the process will be described in detail.

### 2. Generation of 2D Flat Image

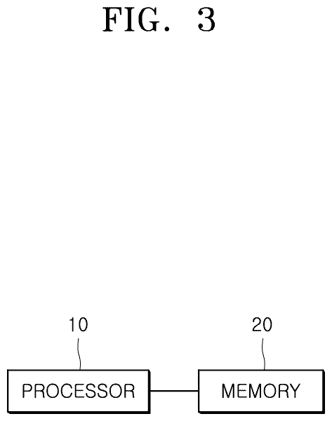

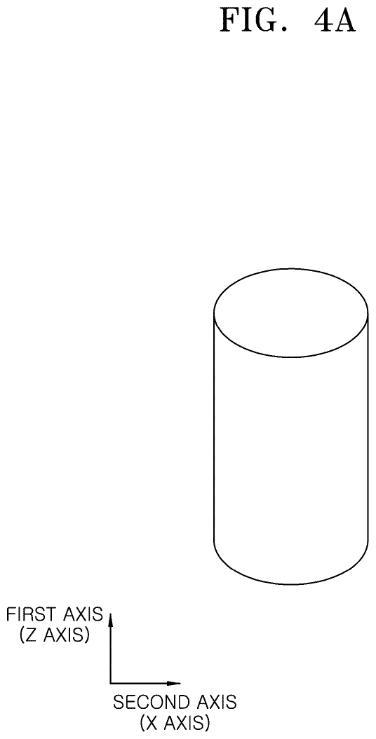

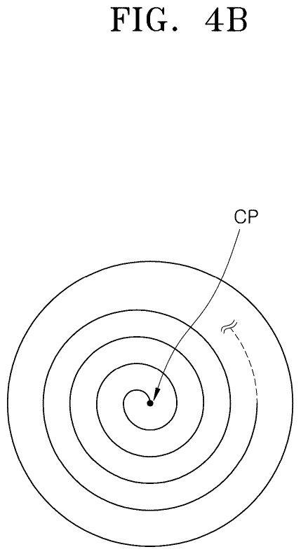

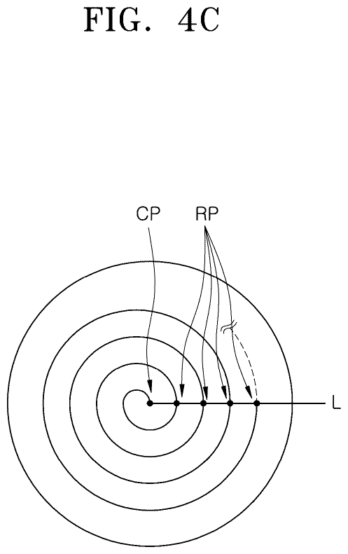

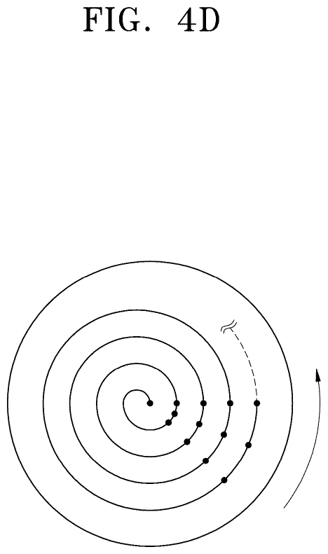

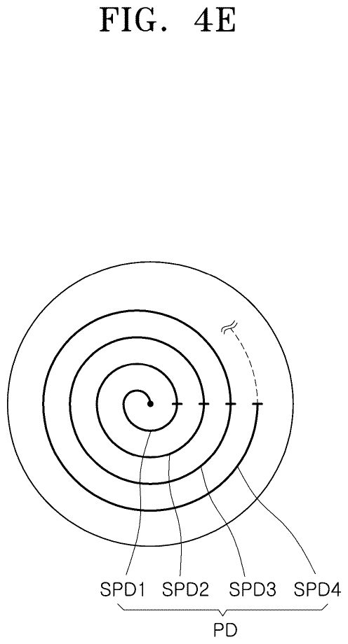

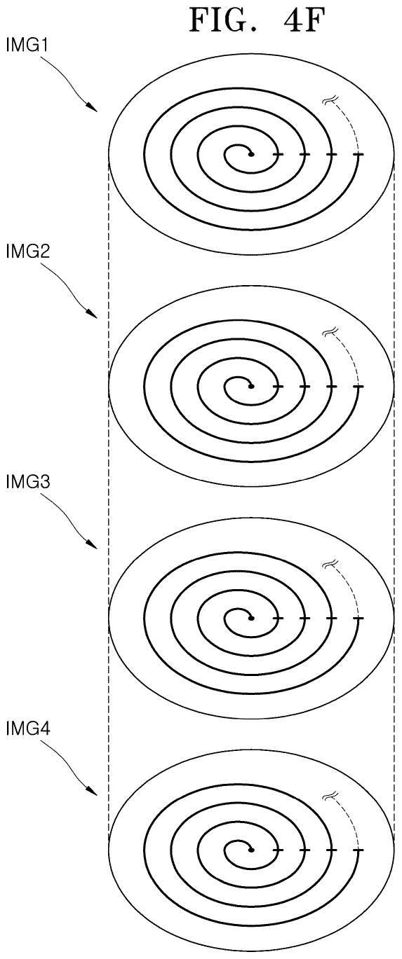

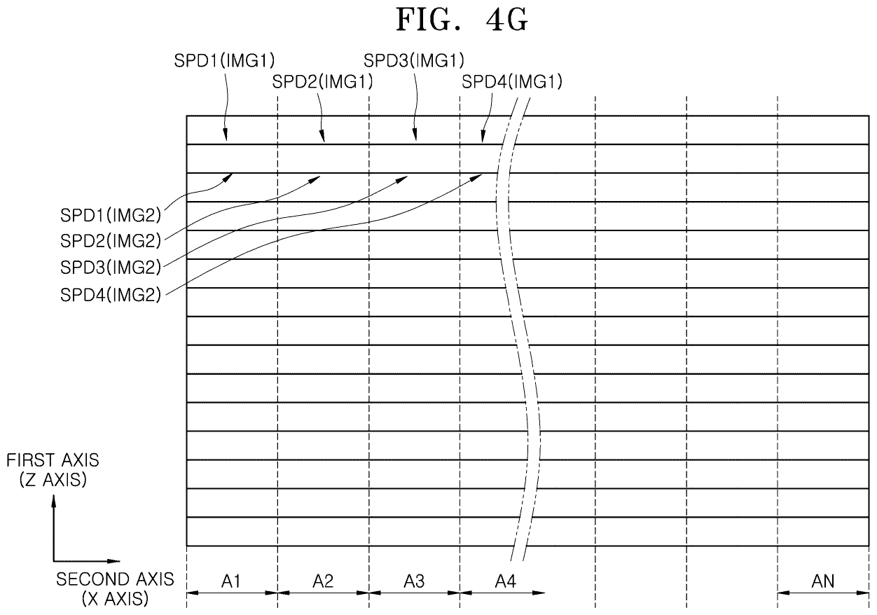

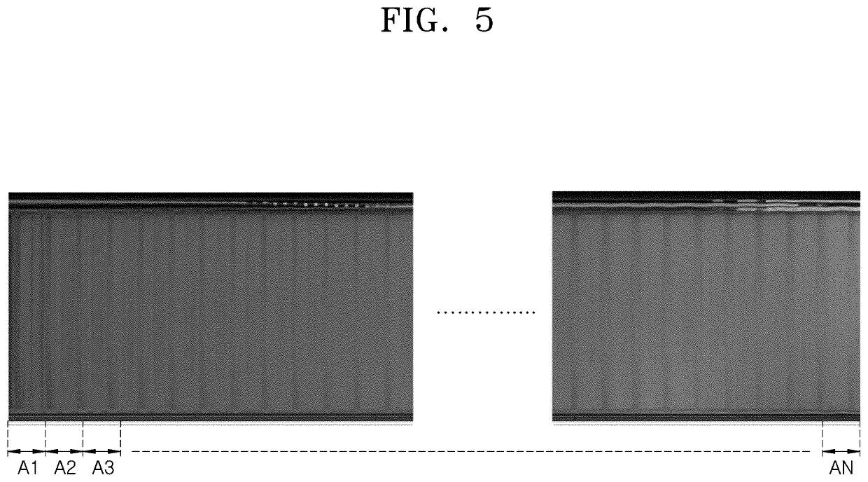

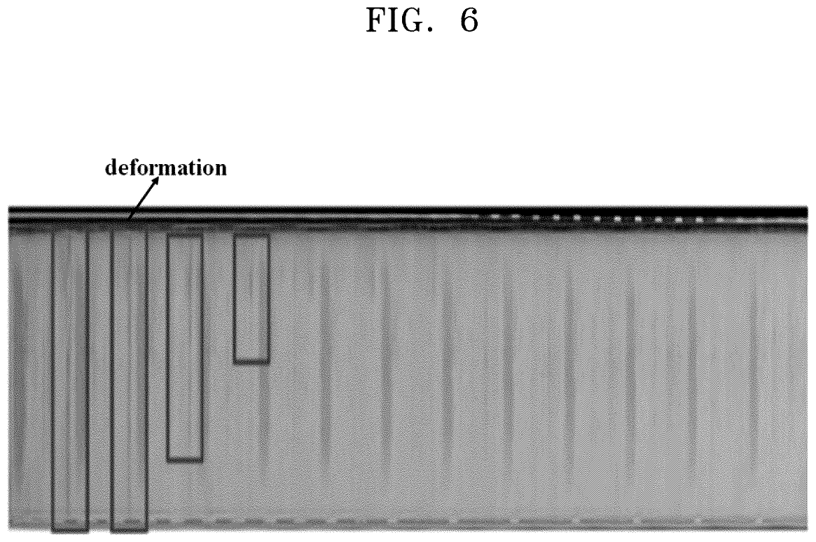

FIG. 3 is a block diagram of a battery diagnosis apparatus according to some embodiments of the present invention. FIGS. 4A-4G illustrate a set of diagrams of a process for generating a 2D flat image from a 3D CT image in a battery diagnosis apparatus according to some embodiments of the present invention. FIG. 5 shows an example of a 2D flat image finally generated in a battery diagnosis apparatus according to some embodiments of the present invention. FIG. 6 shows an example of internal deformation of a battery to be diagnosed in a battery diagnosis apparatus according to some embodiments of the present invention.

As illustrated in FIG. 3, the battery diagnosis apparatus according to some embodiments may include a processor 10 and a memory 20.

The processor 10 is an entity that diagnoses the battery (e.g., battery cell 100) in some embodiments, and may be implemented as a central processing unit (CPU), a system on a chip (SoC), and/or the like, control a plurality of hardware or software components connected to the processor 10 by running an operating system or application, and perform various suitable types of data processing and calculations. The processor 10 may be configured to execute at least one instruction stored in the memory 20 and store result data of the execution in the memory 20.

At least one instruction executed by the processor 10 may be stored in the memory 20. The memory 20 may include a volatile storage medium and/or a non-volatile storage medium, for example, as a read-only memory (ROM) and/or a random access memory (RAM). Further, a 3D CT image of a battery to be diagnosed may be pre-stored in the memory 20, and for example, the 3D CT image may be acquired in advance through a typical CT device for diagnosing an internal state of the battery and pre-stored in the memory 20. FIG. 4A illustrates a conceptual diagram of a 3D CT image.

In order to generate a 2D flat image from a 3D CT image, the processor 10 may first generate a cross-sectional image of the battery from the 3D CT image. When an axis of the battery in a height direction (i.e., the Z-axis in world coordinates) is defined as a first axis, the processor 10 may generate a plurality of cross-sectional images by slicing the 3D CT image at preset intervals relative to a first axis direction with respect to the battery. The number of generated cross-sectional images (e.g., 800 to 1,000) may be set or predetermined based on the size or specifications of the battery to be diagnosed, the designer's intention, and experimental results. In order to help understanding of some embodiments of the present disclosure, FIG. 4F illustrates an example in which four cross-sectional images are provided.

As the 3D CT image is composed of greyscale colors, the cross-sectional image is also composed of greyscale colors. Pixel values of the cross-sectional image indicated below may be greyscale intensity. An outermost part of the cross-sectional image may correspond to a part with a minimum pixel value, corresponding to the cylindrical can 110. Further, according to the winding process of the electrode assembly 120, peaks of the pixel values of the cross-sectional image may repeatedly (e.g., periodically) appear on an imaginary line extending outward from a center of the cross-sectional image.

In some examples, because it is impossible to directly spread out a 3D CT image to generate a 2D flat image, set or predetermined reference data is used to spread out the 3D CT image, and, to this end, the processor 10 may generate plot data used to generate the 2D flat image by spreading out the 3D CT image on the basis of the greyscale structure of the cross-sectional image described above. As used herein, “spreading out” a 3D CT image may mean unrolling or unfolding the 3D CT image.

The processor 10 may plot a plurality of points on the cross-sectional image according to the pixel values of the cross-sectional image to generate plot data in which at least some of the points are rounded.

FIGS. 4B to 4E illustrate a process for generating plot data on a cross-sectional image. First, as illustrated in FIG. 4B, the processor 10 may plot a center point CP on the center of the cross-sectional image. In such examples, the processor 10 may recognize a part of the cylindrical can 110 with a minimum pixel value on the cross-sectional image and plot the center point CP on a center of the recognized part.

Thereafter, as illustrated in FIG. 4C, the processor 10 may plot a plurality of reference points RP on a plurality of positions where peaks of pixel values of the cross-sectional image appear on an imaginary line L extending from the center point CP to one outer side of the cross-sectional image.

Thereafter, as illustrated in FIG. 4D, the processor 10 may generate plot data (e.g., pieces of plot data) PD by continuously plotting points while tracking positions having the same pixel value as the plurality of reference points RP. In the examples of the cylindrical battery cell 100, the processor 10 may generate the plot data (e.g., pieces of plot data) PD by continuously plotting the points with the same pixel value as each reference point RP by rotating the cross-sectional image 360°, as illustrated in FIG. 4D. When the plot data generated for each 360° rotation of the cross-sectional image is defined as subplot data SPD, a number of pieces of subplot data SPD corresponding to the number of windings of the electrode assembly 120 is generated on the cross-sectional image. FIG. 4E illustrates only four pieces of subplot data SPD1 to SPD4 closest to the center of the cross-sectional image among the pieces of plot data PD (in FIG. 4E, a boundary of each piece of subplot data is clearly indicated using a symbol “-”).

The process for generating the plot data illustrated in FIGS. 4B to 4E above is performed on each of a plurality of cross-sectional images generated by the processor 10, and FIG. 4F illustrates an example in which plot data is generated for each of four cross-sectional images IMG1 to IMG4.

Thereafter, the processor 10 may generate a 2D flat image by linearizing the plurality of pieces of plot data generated for each of the plurality of cross-sectional images, that is, generate the 2D flat image by linearizing the round type of plot data in the form of a straight line and spreading out the plurality of cross-sectional images.

In such examples, the processor 10 may generate the 2D flat image by aligning the plurality of pieces of plot data linearized in the form of the straight line relative to the first axis direction (e.g., the Z-axis direction; herein, the “Z-axis direction alignment” and similar language may refer to the radial angles being the same). When described as an example with reference to FIG. 4G, in the examples in which four cross-sectional images are respectively defined as first to fourth cross-sectional images IMG1 to IMG4 and four pieces of subplot data closest to a center of the cross-sectional image are respectively defined as pieces of first to fourth subplot data SPD1 to SPD4, the pieces of first subplot data SPD1 of each of the cross-sectional images IMG1 to IMG4 may be aligned in the Z-axis direction, the pieces of second subplot data SPD2 of each of the cross-sectional images IMG1 to IMG4 may be aligned in the Z-axis direction, the pieces of third subplot data SPD3 of each of the cross-sectional images IMG1 to IMG4 may be aligned in the Z-axis direction, and the pieces of fourth subplot data SPD4 of each of the cross-sectional images IMG1 to IMG4 may be aligned in the Z-axis direction.

Accordingly, as illustrated in FIG. 4G, the 2D flat image is divided into first to N^{th} zones A1 to AN (N being an integer greater than one) relative to a start or end point of the subplot data linearized in the form of the straight line in a second axis direction (e.g., the radial direction of the cylindrical battery cell 100, e.g., the X-axis), the number of zones (i.e., a value of N) corresponds to the number of windings of the electrode assembly 120, and each zone corresponds to an area of the electrode assembly 120 wound at 360°.

FIG. 5 shows an example of a finally generated 2D flat image. In FIG. 5, each of zones A1 to AN corresponds to an area of the electrode assembly 120 wound at 360°. Based on the 2D flat image shown in FIG. 5, the processor 10 diagnoses deformation of an internal structure of the battery cell 100 as illustrated as an example in FIG. 6.

### 3. Diagnosis of Deformation of Internal Structure of Battery Cell

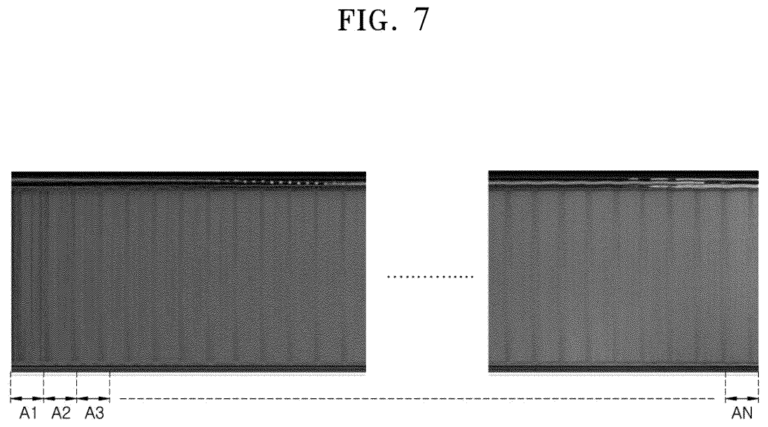

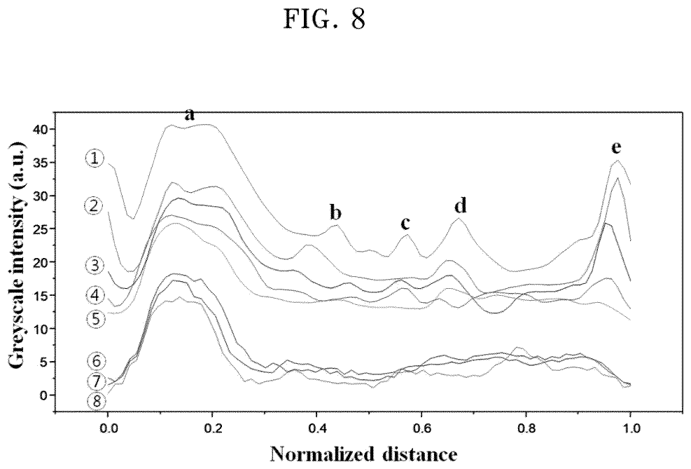

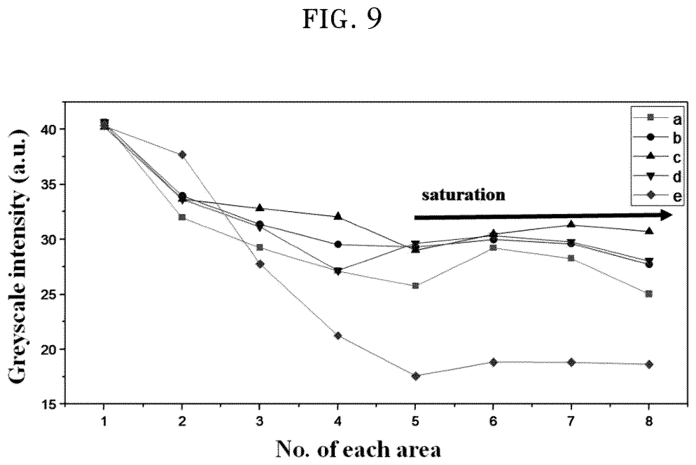

FIG. 7 shows an example of first to N^{th} zones of a 2D flat image in a battery diagnosis apparatus according to some embodiments of the present invention, and FIGS. 8 and 9 show examples of a process for diagnosing internal deformation of a battery in a battery diagnosis apparatus according to some embodiments of the present invention.

In the related art, in order to diagnose deformation of an internal structure of a battery cell, methods of measuring electrochemical data (e.g., capacity data (Ah)) of the battery cell or visually checking the above-described 3D CT image were mainly used. However, in the example of minute deformation that occurs in an early stage in which the internal structure of the battery cell is deformed, there is a problem in that the methods of the related art are not suitable for diagnosing the battery cell because rapid electrochemical changes in battery cell do not occur and visual confirmation through the 3D CT image is difficult.

For example, when the charging/discharging cycle of a battery cell exceeds a certain level, the capacity of the battery cell rapidly decreases and a shading change that can be seen with the naked eye appears in a 3D CT image, and thus the electrochemical data measurement methods and visual confirmation methods of 3D CT images of the related art may be effectively used. However, when the charging/discharging cycle of the battery cell is less than or equal to the certain level (e.g., the initial cycle), there is no significant change in capacity of the battery cell and there is no change that can be seen with the naked eye in the 3D CT image, and thus the electrochemical data measurement methods and visual confirmation methods of 3D CT images of the related art cannot be effectively used.

To this end, some embodiments of the present disclosure provide a solution that can diagnose even minute deformation that occurs in the initial stage in which the internal structure of the battery cell 100 is deformed, and the solution will be described in further detail below (it is assumed that the 2D flat image described above has been generated).

First, the processor 10 may divide the 2D flat image into a plurality of zones. That is, as described above, the processor 10 may divide the 2D flat image into a first to N^{th} zones relative to the start or end point of the subplot data linearized in the form of the straight line in the second axis direction (e.g., radial direction of the cylindrical battery cell 100, e.g., the X-axis). FIG. 7 shows an example of first to N^{th} zones A1 to AN of the 2D flat image. The first and N^{th} zones A1 and AN correspond to a winding core and winding end of the battery cell 100, respectively.

Thereafter, the processor 10 may diagnose deformation of the internal structure of the battery on the basis of changes in pixel values between the plurality of zones.

As a process for identifying the changes in pixel values between the plurality of zones, the processor 10 may identify a plurality of peak positions where peaks of the pixel values appear in each zone. The plurality of peak positions may have values normalized based on a specific position of the 2D flat image (e.g., a center of the cylindrical can 110, a position where the center point CP is plotted when the 2D flat image is generated).

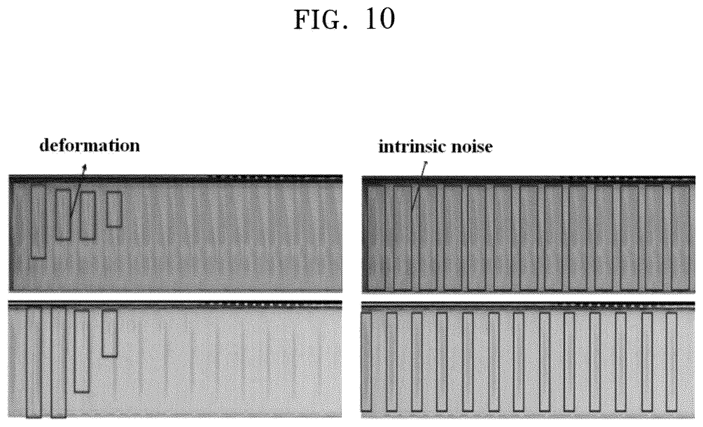

FIG. 8 shows a plurality of peak positions where peaks of pixel values appear in first to eighth zones 1 to 8 (shown in FIG. 10) of a 2D flat image. In FIG. 8, a horizontal axis is a normalized distance based on a specific position of the 2D flat image, and a vertical axis is greyscale intensity. Considering that a winding core part of a cylindrical battery cell typically causes greater deformation of the internal structure than a winding end part, a plurality of peak positions where peaks of pixel values appear may be identified based on the first zone 1) corresponding to the winding core part. FIG. 8 shows an example in which peak positions a to e are identified as five peak positions.

When a process for analyzing a change in peak of a pixel value corresponding to a specific peak position that appears across a plurality of zones is defined as a peak change analysis process, the processor 10 may repeatedly perform the peak change analysis process on each of the plurality of peak positions and then diagnose deformation of the internal structure of the battery on the basis of the results of the repeated performance. According to the example of FIG. 8, the peak change analysis process is performed five times on each of the peak positions a to e, and FIG. 9 shows results of the performance.

As shown in FIG. 9, when the peak change analysis process is completed for each of the plurality of peak positions, the processor 10 may diagnose deformation of the internal structure of the battery by analyzing a change rate of the peak of the pixel value corresponding to each peak position that appears across an analysis target section within the plurality of zones. In such examples, the processor 10 may diagnose the deformation of the internal structure of the battery excluding a saturation section in which the change rate of the peak of the pixel value corresponding to each peak position is saturated from the plurality of zones. That is, as shown in FIG. 9, as the possibility of deformation of the internal structure decreases from the winding core part of the battery cell 100 to the winding end part, there may be a saturation section where the change rate of the peak of the pixel value converges to a specific value (in order to determine the saturation section, for example, quantitative criteria such as determining a section in which a slope in FIG. 9 is less than or equal to a specific value (e.g., 1) may be predefined in the processor 10). Because diagnosis of the deformation of internal structure is not required in the saturation section, the processor 10 may diagnose the deformation of the internal structure of the battery by analyzing the change rate of the peak of the pixel value corresponding to each peak position for a section (defined as a diagnosis target section) in which the saturation section is excluded from the plurality of zones. In the example of FIG. 9, the diagnosis target section corresponds to a section from first to fifth zones.

The processor 10 may determine that the deformation of the internal structure of the battery has occurred at a peak position corresponding to an outlier change rate among a plurality of change rates for each peak position in the diagnosis target section. The change rate may be the slope in FIG. 9.

For example, referring to FIG. 9, a change rate of a peak of a pixel value corresponding to each of peak positions a to d in the diagnosis target section shows a similar trend, and this means that the peak positions a to d appear in similar patterns in the first to fifth zones. Shading due to the brightness and darkness of the CT image itself (i.e., intrinsic noise to be described below) has periodicity due to the winding structure of the electrode assembly 120 within the cylindrical battery cell 100, the periodicity in which the peak positions a to d appear in similar patterns in the first to fifth zones can be seen as being caused by shading due to the brightness and darkness of the CT image itself, and thus the processor 10 may determine that the peak positions a to d are not caused by the deformation of the internal structure of the battery, but rather by shading due to the brightness and darkness of the CT image itself.

On the other hand, a change rate of a peak of a pixel value corresponding to a peak position e shows a different tendency compared to the change rate of the other peak positions, that is, shows a tendency for an absolute value of the change rate to be different compared to the change rates of the peak positions a to d. Because there is no similar trend with the change rates of the peaks of the pixel values corresponding to the peak positions a to d, the processor 10 may determine that the deformation of the internal structure of the battery has occurred at the peak position e.

In some examples, as a statistical method of identifying the outlier change rate from among the plurality of change rates for each peak position, known scatter plots such as interquartile range (IQR), variance, deviation, or standard deviation may be employed.

Additionally, the processor 10 may determine the deformation of the internal structure of the battery more precisely using the electrochemical data measurement method of the related art together with the process for determining the deformation of the internal structure of the battery according to the above-described process.

### 4. Distinguishing Topology of Intrinsic Noise of CT Image and Deformation of Battery Cell

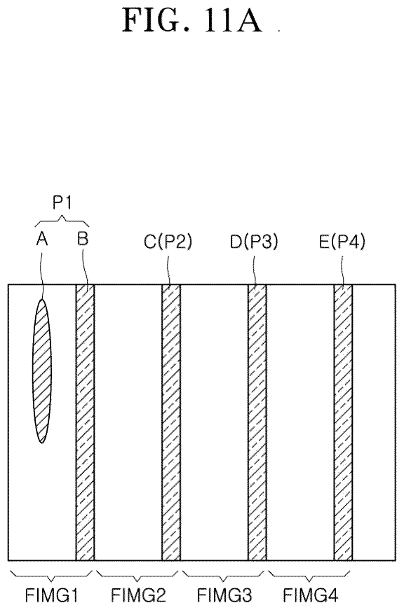

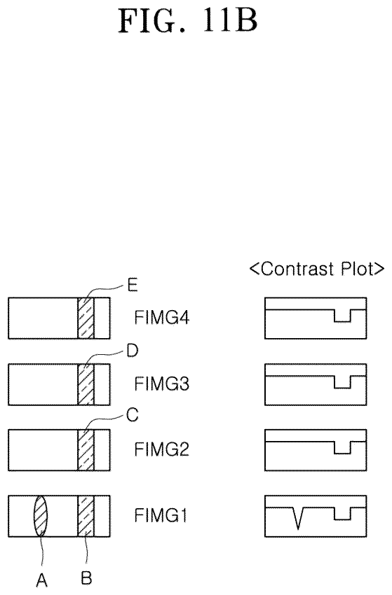

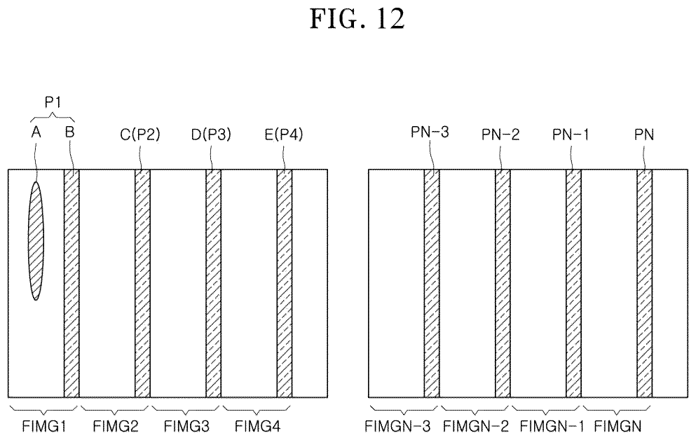

FIG. 10 shows an example of an intrinsic noise area reflected in a 2D flat image and an internal deformation area of a battery in a battery diagnosis apparatus according to some embodiments of the present invention, and FIGS. 11 and 12 show examples of a process for distinguishing between an intrinsic noise area reflected in a 2D flat image and an internal deformation area of a battery in a battery diagnosis apparatus according to some embodiments of the present invention.

As described above, some embodiments of the present disclosure operate to determine deformation of the internal structure of the battery on the basis of the peaks (i.e., shade change) of the pixel values in each zone of the 2D flat image. In some examples, because the 2D flat image basically corresponds to the CT image, there is shading (defined as intrinsic noise according to some embodiments) due to the brightness and darkness of the CT image itself in the 2D flat image, and there is a problem in that it is difficult to distinguish between the inherent noise and the shading caused by the deformation of the internal structure of the battery because their intensities and shapes are similar.

Because the shading caused by the deformation of the internal structure of the battery appears only in the zone where the deformation has occurred, the shading locally appears on the 2D flat image and mainly appears at the upper and middle parts of the electrode assembly 120, as shown in FIG. 10. On the other hand, because the shading of the original 3D CT image is directly reflected in the shading caused by the intrinsic noise of the CT image, the shading caused by the intrinsic noise of the CT image has the characteristic of appearing throughout the upper, middle, and lower parts of the cylindrical battery cell 100 and appearing repeatedly throughout the image. In some embodiments, a configuration is adopted in which the intrinsic noise of the CT image and the internal deformation of the battery are distinguished based on the size and regularity of the intrinsic noise.

The processor 10 may diagnose the battery by analyzing a pattern of pixel values of the 2D flat image and distinguishing between intrinsic noise reflected in the 2D flat image and an abnormality of the battery (i.e., deformation of the internal structure).

For example, the processor 10 divides the 2D flat image into first to N^{th} zones on the basis of a start or end point of subplot data linearized in the form of a straight line in a second axis direction of the 2D flat image (e.g., radial direction of the cylindrical battery cell 100, e.g., the X-axis), and distinguishes between the intrinsic noise and the deformation of the internal structure of the battery by identifying regularity of the pattern of the pixel values in the plurality of zones.

When parts of the 2D flat image for the first to N^{th} zones, which are the plurality of zones, are respectively defined as first to N^{th} flat images and areas where peaks of pixel values of the first to N^{th} flat images appear are respectively defined as first to N^{th} peak areas, the processor 10 may distinguish between the intrinsic noise and the deformation of the internal structure of the battery by comparing and analyzing the first to N^{th} peak areas.

An example in which first to fourth flat images FIMG1 to FIMG4 are provided for the first to fourth zones A1 to A4 will be described further with reference to FIGS. 11A-B. FIGS. 11A and 11B show examples of first to fourth peak areas P1 to P4 where peaks of pixel values of the first to fourth flat images FIMG1 to FIMG4 appear. As shown in FIG. 11B, the processor 10 may identify intrinsic noise by analyzing positions of the first to fourth peak areas P1 to P4 with the first to fourth flat images FIMG1 to FIMG4 aligned relative to a first axis direction (e.g., the Z-axis direction).

In such examples, the processor 10 may identify an area corresponding to an inlier as an intrinsic noise area on the basis of an overlapping position thereof (e.g., it may correspond to a normalized distance on a horizontal axis of FIG. 8) from among entire areas of the first to fourth peak areas P1 to P4, and identify an area corresponding to an outlier as a deformation area of the internal structure of the battery. That is, the inlier area means that the peaks of the pixel values have regularity and the outlier area means that there is no regularity, and thus the processor 10 may distinguish between the intrinsic noise area and the deformation area of the internal structure by distinguishing between the inlier area and the outlier area. In FIG. 11B, from among the entire areas of the first to fourth peak areas P1 to P4, the peak areas corresponding to the inlier correspond to areas B to E and the peak area corresponding to the outlier corresponds to area A, and thus the processor 10 may identify the areas B to E as the intrinsic noise area and identify the area A as the deformation area of the internal structure of the battery. When the intrinsic noise area and the deformation area of the internal structure are distinguished, a contrast plot image of each flat image may be used as shown in FIG. 11B.

In some examples, as a statistical method of identifying the areas corresponding to the inlier and the outlier on the basis of the overlapping position thereof from among the entire areas of the first to fourth peak areas P1 to P4, known scatter plots such as IQR, variance, deviation, or standard deviation may be employed.

As another method of distinguishing between the intrinsic noise area and the deformation area of the internal structure, a method of analyzing a shading pattern of the winding core part on the basis of a shading pattern of the winding end part of the battery cell 100 may be provided in consideration of the fact that the winding core part of the cylindrical battery cell 100 causes greater deformation of the internal structure than the winding end part.

The above method may be expressed quantitatively as follows. The processor 10 may use an M^{th} peak area (corresponding to an M^{th} flat image) as a reference to identify a K^{th} peak area (corresponding to a K^{th} flat image), which has a different position from the M^{th} peak area, as the deformation area of the internal structure of the battery (M and K are natural numbers less than or equal to N, M>K). Here, the M^{th} peak area may correspond to a peak area (e.g., an N^{th} peak area) at the winding end part of the battery cell 100, and the K^{th} peak area may correspond to a peak area (e.g., a first peak area) at the winding core part of the battery cell 100.

In such examples, rather than using one flat image corresponding to the winding core part and winding end part, a plurality of flat images may be used as shown in FIG. 12. That is, as shown in FIG. 12, the processor 10 may prepare first to fourth flat images FIMG1 to FIMG4 (i.e., winding core parts) having first to fourth peak areas P1 to P4 and (N−3)^{th} to N^{th} flat images FIMGN-3 to FIMGN (i.e., winding end parts), and then identify an area (e.g., area A in FIG. 12) having a different position from (N−3)^{th} to N^{th} peak areas PN−3 to PN from among entire areas of the first to fourth peak areas P1 to P4 as the deformation area of the internal structure of the battery.

The processor 10 may remove the intrinsic noise of the CT image identified through the above process from the 2D flat image and then diagnose the deformation of the internal structure of the battery, and thus diagnosis performance and accuracy may be improved (e.g., increased).

### 5. Battery Diagnosis Method

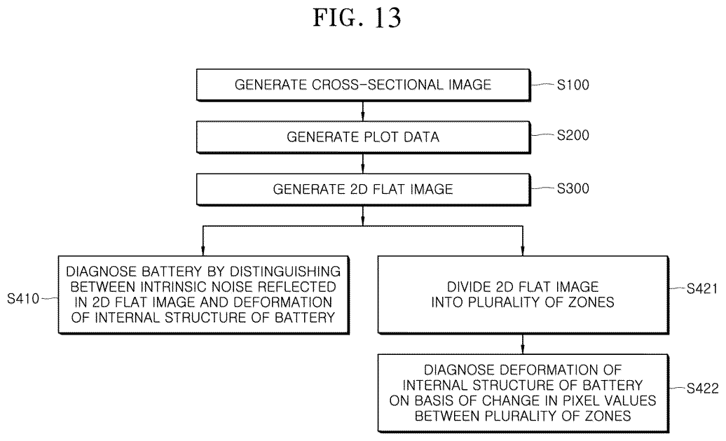

FIG. 13 is a flowchart of a battery diagnosis method according to some embodiments of the present invention. The battery diagnosis method according to some embodiments will be described with reference to FIG. 13, and detailed description of parts that overlap with the above-described content will be omitted and a time series configuration thereof will be mainly described.

First, the processor 10 generates a cross-sectional image of a battery from a 3D image of the battery (S100). In operation S100, the processor 10 may generate a plurality of cross-sectional images by slicing the 3D image at preset intervals relative to a first axis direction with respect to the battery.

Next, the processor 10 plots a plurality of points on the cross-sectional image according to pixel values of the cross-sectional image generated in operation S100 to generate plot data in which at least some of the points are rounded (S200). In operation S200, the processor 10 generates the plot data by plotting a center point on a center of the cross-sectional image, plotting a plurality of reference points on a plurality of positions where peaks of the pixel values of the cross-sectional image appear on an imaginary line extending from the center point to an outside of the cross-sectional image, and plotting points while tracking positions having the same pixel value as the plurality of reference points. The plot data is generated for each of the plurality of cross-sectional images generated in operation S100.

Next, the processor 10 generates a 2D flat image, in which the 3D image of the battery is spread out, by linearizing the plot data generated in operation S200 (S300). In operation S300, the processor 10 generates the 2D flat image by linearizing the plurality of pieces of plot data generated for each of the plurality of cross-sectional images and aligning the plurality of pieces of linearized plot data relative to the first axis direction.

Next, the processor 10 diagnoses deformation of an internal structure of the battery on the basis of the 2D flat image generated in operation S300 (S410+S421+S422). Here, the operations of the processor 10 may include i) an operation S410 of distinguishing between an intrinsic noise area and a deformation area of the internal structure and ii) the operations S421+S422 of diagnosing minute deformation of the internal structure of the battery cell 100, and operations S410 and S421+S422 may be implemented in a parallel configuration in which operations S410 and S421+S422 are performed independently or may be implemented in a time series configuration in which operations S421+S422 are performed after operation S410 is performed.

First, in operation S410, the processor 10 diagnoses the battery by analyzing a pattern of the pixel values on the 2D flat image and distinguishing between intrinsic noise reflected in the 2D flat image and deformation of the internal structure of the battery.

For example, the processor 10 divides the 2D flat image into a plurality of zones, and distinguishes between the intrinsic noise and the deformation of the internal structure of the battery by identifying regularity of the pattern of the pixel values in the plurality of zones. When parts of the 2D flat image for the first to N^{th} zones, as the plurality of zones, are respectively defined as first to N^{th} flat images and areas where peaks of the pixel values of the first to N^{th} flat images appear are respectively defined as first to N^{th} peak areas (where N is a natural number of 2 or more), in operation S410, the processor 10 distinguishes between the intrinsic noise and the deformation of the internal structure of the battery by comparing and analyzing the first to N^{th} peak areas.

In such examples, the processor 10 identifies the intrinsic noise by analyzing positions of the first to N^{th} peak areas with first to fourth flat images aligned relative to the first axis direction.

For example, the processor 10 identifies an area corresponding to an inlier as the intrinsic noise on the basis of an overlapping position thereof from among the first to N^{th} peak areas, and identifies an area corresponding to an outlier as the deformation area of the internal structure of the battery.

In some examples, in operation S410, the processor 10 may use an M^{th} peak area as a reference to identify a K^{th} peak area, which has a different position from the M^{th} peak area, as the deformation area of the internal structure of the battery (where M and K are natural numbers less than or equal to N, and M>K).

Next, in operations S421+S422, the processor 10 first divides the 2D flat image into the plurality of zones (S421).

Next, the processor 10 diagnoses the deformation of the internal structure of the battery on the basis of a change in pixel values between the plurality of zones (S422).

In operation S422, the processor 10 identifies a plurality of peak positions where peaks of the pixel values appear in each zone, and in such examples, the plurality of peak positions may have values normalized based on a specific position of the 2D flat image.

When a process for analyzing a change in peak of a pixel value corresponding to a specific peak position that appears across a plurality of zones is defined as a peak change analysis process, in operation S422, the processor 10 repeatedly performs the peak change analysis process on each of the plurality of peak positions and then diagnoses deformation of the internal structure of the battery on the basis of the results of the repeated performance.

In operation S422, the processor 10 diagnoses the deformation of the internal structure of the battery by analyzing a change rate of the peak of the pixel value corresponding to each peak position that appears across a diagnosis target section within the plurality of zones, and for example, the processor 10 determines that the deformation of the internal structure of the battery has occurred at a peak position corresponding to an outlier change rate among a plurality of change rates for each peak position. The above-described diagnosis target section is a section excluding a saturation section in which the change rate of the peaks of the pixel value corresponding to each peak position is saturated from the plurality of zones.

In some examples, the battery diagnosis method according to some embodiments may be written as a computer program for executing operations S100 to S410, S421, and S422 described above in combination with hardware, and may be stored in a computer-readable recording medium and may be implemented in a general-purpose digital computer that operates the computer program. Examples of the computer-readable recording medium include a ROM, a RAM, magnetic media such as a hard disk, a floppy disk, and a magnetic tape, optical media such as a compact disc read-only memory (CD-ROM) and a digital video disc (DVD), magneto-optical media such as a floptical disk, and a hardware device such as a flash memory, that is specially made to store and perform program instructions.

According to some embodiments, in order to diagnose the battery cell 100, 3D CT image-based nondestructive analysis is applied, and thus internal damage to the battery cell that is caused by application of destructive analysis can be removed, the actual cause of the battery cell's performance deterioration can be identified, and the tendency of deformation according to charging and discharging can be more easily confirmed.

The embodiments described herein may be implemented, for example, as a method or process, an apparatus, a software program, a data stream, and/or a signal. Although discussed only in the context of a single form of implementation (e.g., only as a method), the discussed features may also be implemented in other forms (e.g., devices or programs). The apparatuses may be implemented in appropriate hardware, software, firmware, etc. The methods may be implemented in devices such as processors, which generally refer to processing devices that include computers, microprocessors, integrated circuits, programmable logic devices, etc. Further, the processors include communication devices such as computers, cellular phones, portable/personal digital assistants (PDAs), other devices, etc. that facilitate the communication of information between end-users.

According to some embodiments of the present invention, in order to diagnose a battery cell, 3D CT image-based nondestructive analysis is applied, and thus internal damage to the battery cell that is caused by application of destructive analysis can be removed, the actual cause of the battery cell's performance deterioration can be identified, and the tendency of deformation according to charging and discharging can be more easily confirmed.

However, effects that can be achieved through the present invention are not limited to the above-described effects and other effects that are not described may be clearly understood by those skilled in the art from the above detailed descriptions.

While the present invention has been described with reference to specific embodiments and drawings, the present invention is not limited thereto. It is clear by those skilled in the art that various suitable modifications and alterations may be made without departing from the spirit and scope of the present invention, as defined by the appended claims and equivalents thereof.

What is claimed is:

1. An apparatus for diagnosing a battery, the apparatus comprising:
a processor; and
a memory storing instructions that, when executed on the processor, cause the processor to perform:
generating a plurality of cross-sectional images of the battery from a three-dimensional (3D) image of the battery;
plotting a plurality of points according to pixel values of a cross-sectional image of the plurality of cross-sectional images on the cross-sectional image to generate plot data in which at least some of the points are rounded;
generating a two-dimensional (2D) flat image, in which the 3D image of the battery is spread out, by linearizing the generated plot data; and
diagnosing the battery based on the generated 2D flat image.

2. The apparatus of claim 1, wherein the processor is configured to generate the plurality of cross-sectional images by slicing the 3D image at preset intervals relative to a first axis direction with respect to the battery.

3. The apparatus of claim 2, wherein the processor is configured to generate the plot data for each one of the plurality of cross-sectional images, and to generate the 2D flat image by linearizing the plot data generated for each one of the plurality of cross-sectional images.

4. The apparatus of claim 3, wherein the processor is configured to generate the 2D flat image by aligning the plot data relative to the first axis direction.

5. The apparatus of claim 1, wherein, as a process for generating the plot data, the processor is configured to plot a center point on a center of the cross-sectional image, and to plot a plurality of reference points on a plurality of positions where peaks of the pixel values of the cross-sectional image appear on an imaginary line extending from the center point to an outside of the cross-sectional image.

6. The apparatus of claim 5, wherein the processor is configured to generate the plot data by plotting points while tracking positions having same pixel values as the plurality of reference points.

7. The apparatus of claim 1, wherein the 3D image and the cross-sectional images of the battery are implemented as computed tomography (CT) images, and a pixel value of the cross-sectional image is a greyscale intensity of the CT image.

8. The apparatus of claim 1, wherein the processor is configured to diagnose deformation of an internal structure of the battery based on the 2D flat image.

9. A method of diagnosing a battery, the method comprising:
generating, by a processor, a plurality of cross-sectional images of the battery from a three-dimensional (3D) image of the battery;
plotting, by the processor, a plurality of points according to pixel values of a cross-sectional image of the plurality of cross-sectional images on the cross-sectional image and generating plot data in which at least some of the points are rounded;
generating, by the processor, a two-dimensional (2D) flat image, in which the 3D image of the battery is spread out, by linearizing the generated plot data; and
diagnosing, by the processor, the battery based on the generated 2D flat image.

10. The method of claim 9, wherein, in the generating of the cross-sectional images, the processor is configured to generate the plurality of cross-sectional images by slicing the 3D image at preset intervals relative to a first axis direction with respect to the battery.

11. The method of claim 10, wherein the plot data are generated for each one of the plurality of cross-sectional images, and
wherein, in the generating of the 2D flat image, the processor is configured to generate the 2D flat image by linearizing the plot data generated for each one of the plurality of cross-sectional images.

12. The method of claim 11, wherein, in the generating of the 2D flat image, the processor is configured to generate the 2D flat image by aligning the plot data relative to the first axis direction.

13. The method of claim 9, wherein, in the generating of the plot data, the processor is configured to plot a center point on a center of the cross-sectional image, and to plot a plurality of reference points on a plurality of positions where peaks of the pixel values of the cross-sectional image appear on an imaginary line extending from the center point to an outside of the cross-sectional image.

14. The method of claim 13, wherein, in the generating of the plot data, the processor is configured to generate the plot data by plotting points while tracking positions having same pixel values as the plurality of reference points.

15. The method of claim 9, wherein, in the diagnosing of the battery, the processor is configured to diagnose deformation of an internal structure of the battery based on the 2D flat image.

16. A computer program, which is coupled to hardware and stored in a computer-readable storage medium, for performing operations of:
generating a cross-sectional image of a battery from a three-dimensional (3D) image of the battery;
plotting a plurality of points according to pixel values of the generated cross-sectional image on the cross-sectional image and generating plot data in which at least some of the points are rounded;
generating a two-dimensional (2D) flat image, in which the 3D image of the battery is spread out, by linearizing the generated plot data; and
diagnosing the battery based on the generated 2D flat image.
